(19) United States
(12) Patent Application Publication
(10) Pub. No.: US 2018/0322993 A1
(43) Pub. Date: Nov. 8, 2018

(54) MAGNETIC PICK AND PLACE PROBE

(71) Applicant: Intel Corporation, Santa Clara, CA (US)

(72) Inventors: Kyle YAZZIE, Chandler, AZ (US); Pramod MALATKAR, Chandler, AZ (US)

(21) Appl. No.: 15/770,747

(22) PCT Filed: Dec. 21, 2015
(86) PCT No.: PCT/US2015/066984

§ 371 Date: Apr. 24, 2018

(51) Int. Cl. H01F 7/02; B25J 15/06; G01R 1/067

(52) U.S. Cl. CPC H01F 7/0257; G01R 1/06705; B25J 15/0608

(57) ABSTRACT

A magnetic pick and place probe includes an outer sheath, an inner sheath to vertically slide within the outer sheath, None or more sheath magnets attached to a bottom end of the inner sheath and a tip positioned at a bottom end of the outer sheath to simultaneously pick up an array of magnets for placement on a substrate.

### FIELD

The present disclosure generally relates to pick and place probes for integrated circuit assembly.

### BACKGROUND

Depth sensing camera modules measure three-dimensional (3D) shape information, which enable implementation in novel applications. Such applications include, gesture control of computers, 3D photography, 3D immersive gaming, face recognition in-lieu of alphanumerical passwords, drone and robot control, etc. Depth sensing cameras may utilize stereoscopic imaging, coded light, or laser time of flight. These camera systems utilize increasingly complex opto-mechanical components, including LEDs, lenses, and Micro-electro-mechanical systems (MEMS).

Particular MEMS may be magnetically driven using an array of small magnets. Power characteristics of magnetically driven MEMS decreases rapidly if the magnets do not have a flush alignment with the MEMS. Thus, to assemble the array of magnets, mechanical or vacuum pick and place tooling (e.g., gripper) must grab and place a single magnet. How close the magnets can be brought to the MEMS depends on the inherent accuracy of the tool and whether a second push step is needed to slide the magnets closer to the MEMS. However, an additional push step increases throughput time.

### BRIEF DESCRIPTION OF THE DRAWINGS

FIG. 1 illustrates shows a schematic side view representation of an embodiment of a system suitable to assemble a substrate.

FIG. 2 illustrates a top view of a portion of the system;

FIGS. 3A-3D illustrate embodiments of a probe to pick and place magnets.

FIGS. 4A-4F illustrate embodiments of a probe placing magnets on a MEMS device.

FIG. 5 is a graph illustrating one embodiment of data corresponding to implementation of a magnetic probe.

FIG. 6 illustrates a schematic side view representation of another embodiment system suitable to assemble a substrate;

FIG. 7 shows a top view of a portion of the system of FIG. 6.

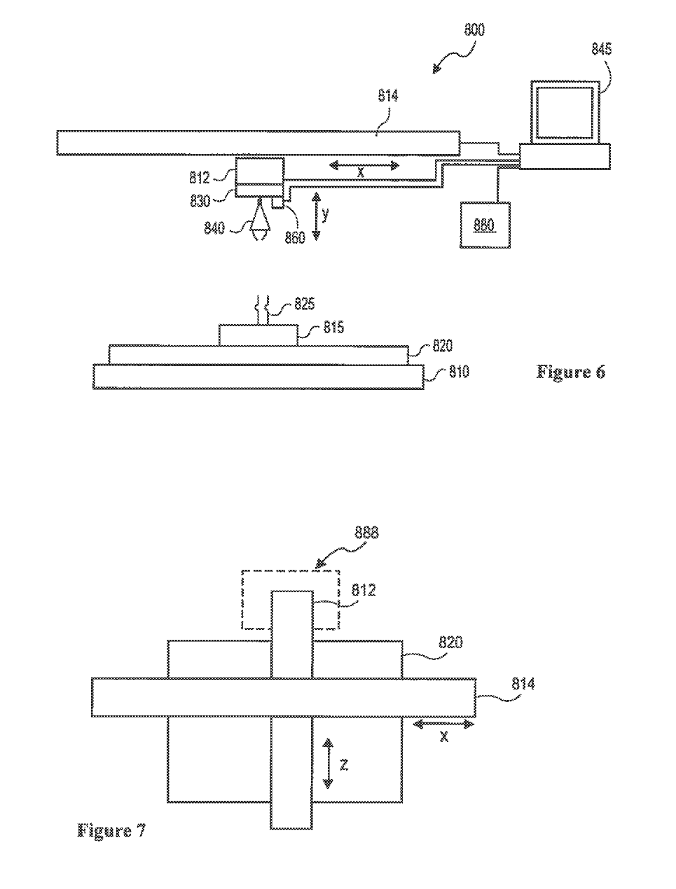

### DETAILED DESCRIPTION

In the following description, numerous specific details are set forth in order to provide a thorough understanding of various embodiments. However, various embodiments of the invention may be practiced without the specific details. In other instances, well-known methods, procedures, components, and circuits have not been described in detail so as not to obscure the particular embodiments of the invention.

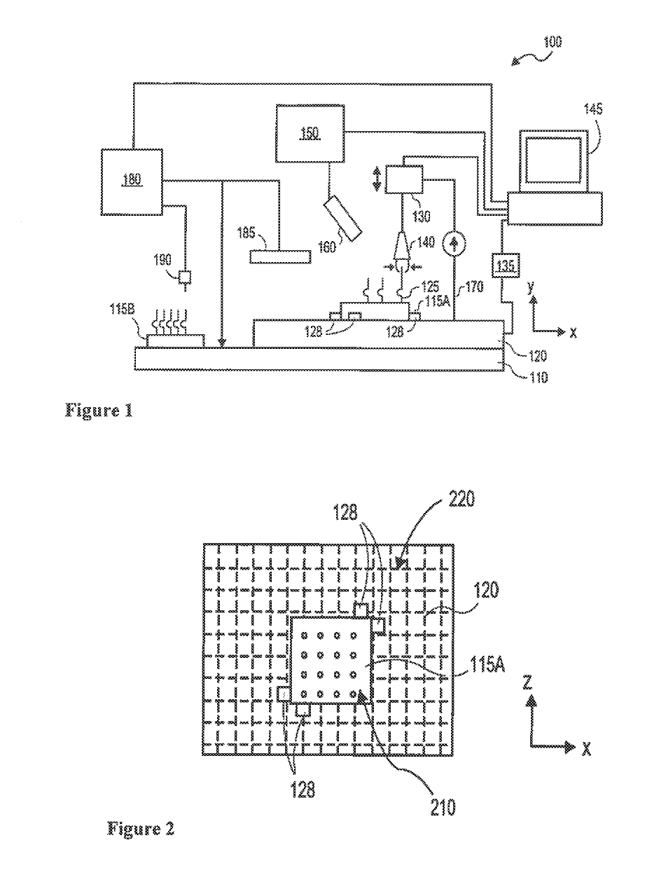

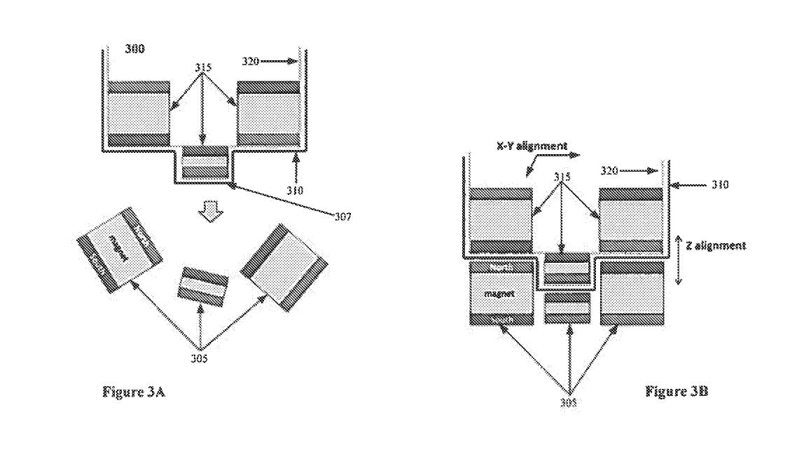

FIG. 1 illustrates one embodiment of a system 100 that may be used for the automated assembly of a probe card substrate. System 100 includes platform 110 onto which substrate 120 is mounted. Substrate 120, in one embodiment, has a surface area that can accommodate a probe head or a full probe card. In this embodiment, substrate 120 is a substrate that is translatable in an x- and a z-direction. Representatively, substrate 120 is translatable in x and y directions according to a grid system configurable for the pitch of a probe card substrate. A representative pitch is on the order of 40 microns (μm) to 130 μm. It is appreciated that other pitches may be utilized. FIG. 2 shows a top view of substrate 120 and illustrates the xz-pitch 220 in a grid of dashed lines. Control of the translation of substrate 120 is provided by machine-readable instructions in processor 145 to which substrate 120 is connected through motor 135. In one embodiment, placement of a probe card substrate, such as probe card substrate 115A, which includes probes 125, on substrate 120 is controlled so that its location and x- and z-coordinates are known by processor 145. One way the placement of a probe card substrate 115A on substrate 120 is known is by alignment blocks 128 on substrate 120.

Referring again to FIG. 1, also connected to processor 145 is robot 130. The term robot is to be interpreted broadly as a conveyance, transfer device, electro-mechanical transfer device or mechanism, or automatically controlled, reprogrammable, multipurpose manipulator programmable in three, four, or more axes. Robot 130 may take various forms or configurations, consistent with its intended purpose. For example, in various embodiments, robot 130 may be a Gantry or Cartesian coordinate type robot, a selective compliant assembly robot arm (SCARA) type robot, an articulated arm type robot, or a combination thereof (e.g., a SCARA type robot coupled in a Gantry type robot configuration).

In one or more embodiments, robot 130 may have a robotic arm or other mechanical limb. The arm or limb may include an interconnected set of two or more links and one or more powered joints. In one or more embodiments, the arm or limb may allow rotation or movement in at least four axes. As is known, the flexibility or freedom of movement of the arm increases with increasing number of axes. The arm or limb may support and move an end-of-arm tooling or other end effector that is connected at the end of the arm or limb.

The end effector may allow the robot to perform certain intended functions, such as, for example, engaging with an item (e.g., a probe), holding and moving the item, and disengaging from the item. In one or more embodiments, the end effector may include gripper 140. Gripper 140 may serve as a “hand” to grasp, clasp, or otherwise engage with, hold and move, and disengage from a probe.

According to one embodiment, the probe is a magnetic pick-and-place probe that picks up multiple magnets to enable the magnets to self-align to their positions in the final placement configuration on a substrate such as substrate 120. In such an embodiment, accuracy in a final placement configuration is provided by making the probe match tolerances of the final placement configuration. Thus, multiple magnets may simultaneously be picked up self-aligned to final positions while on the tip of the probe, rather than picking and placing one magnet at a time and trying to accurately place each one.

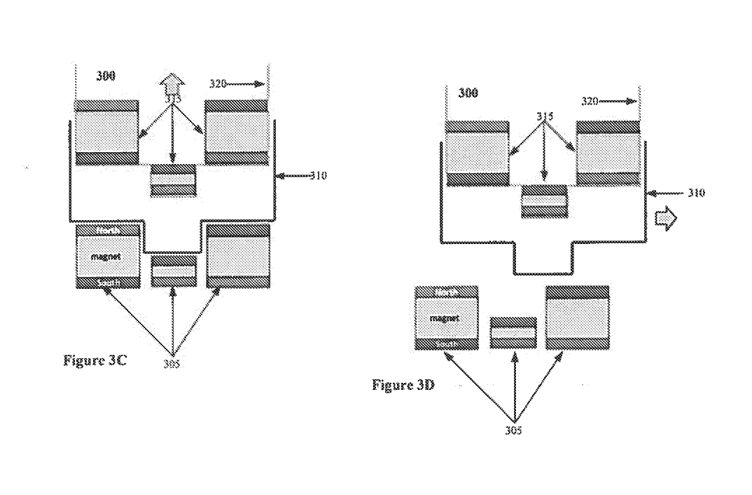

FIGS. 3A-3D illustrate embodiments of a probe 300 implemented to pick and place an array of magnets 305. According to one embodiment, probe 300 is a magnetic probe having magnets constructed from the same magnetic material as magnets 305. However other embodiments may feature different probe 300 and magnet 305 construction materials. In one embodiment, probe 300 includes a tip 307, an outer sheath 310 and an inner sheath 320 movably housed within outer sheath 310. Accordingly, inner sheath 320 is configured to slide vertically within outer sheath 310. Further, sheath magnets 315 are attached to a bottom end of the inner sheath 320. Although shown in FIGS. 3A-3D as having a particular configuration, other embodiments may feature tip 307 that is shaped to conform to any two-dimensional (2D) or 3D arrangement of magnets with same or different heights.

FIG. 3A illustrates probe 300 prior to engaging magnets 305. As shown in FIG. 3A, magnets 315 may be misaligned, such as in a tray. At this stage, inner sheath 320 is positioned at a bottom position to enable magnets 315 to have a flush alignment with tip 307. FIG. 3B shows probe 300 once engaged with magnets 305. Upon engagement, the magnetic force of magnets 315 automatically aligns magnets 305 around tip 307 based on relative the polarities (e.g., north or south) of each of magnets 305 and magnets 315. Thus, tip 307 picks up magnets 305 for placement on a substrate. As shown in FIG. 3B, each magnet 305 is aligned with a corresponding magnet 315.

According to one embodiment, the x-y alignment of magnets 305 is controlled by the layout of magnets 315, while the z alignment is controlled by the shape of probe 307. FIG. 3C shows probe 300 after actuation. As shown in FIG. 3C, inner sheath 320 actuation results in inner sheath 320 being pulled from the bottom of outer sheath 310, resulting in magnets 315 being disengaged from magnets 305. Accordingly, magnets 305 are held in place by outer sheath 310. FIG. 3D shows magnets 305 being aligned after removal of probe 300.

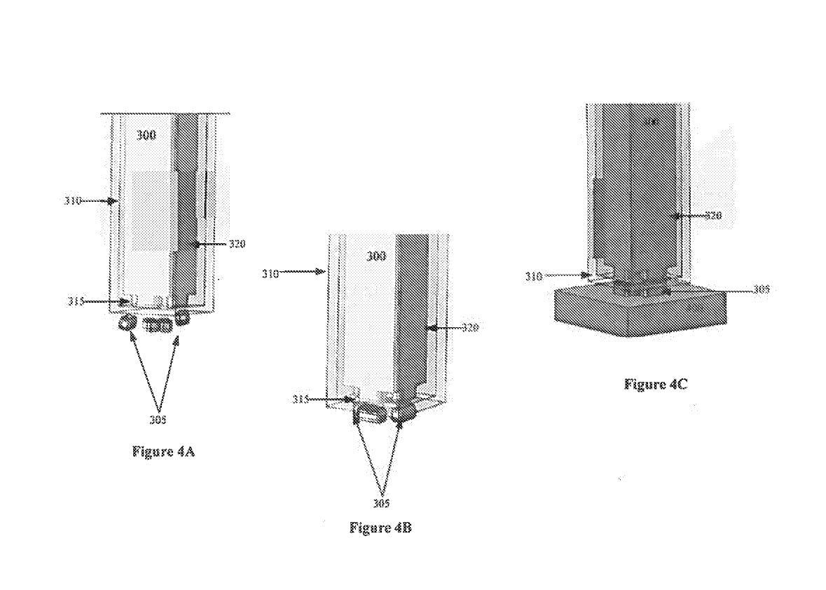

FIGS. 4A-4F illustrate embodiments of a probe picking and placing a square array of four magnets that are to be placed next to the sides of a square MEMS device. FIG. 4A illustrates probe 300, having outer sheath 310 and outer sheath 320 prior to engaging magnets 305. FIG. 4B shows magnets 305 being self-aligned with probe 300 based on the magnetic polarity of magnets 315. FIG. 4C shows probe 300 placing magnets 305 on a substrate 400. In such an embodiment, magnets 305 are placed adjacent to a MEMS device 410. FIG. 4D shows inner sheath 320 being pulled within outer sheath 310, resulting in magnets 315 being disengaged from magnets 305 as inner sheath 320 is pulled from the bottom of outer sheath 310. At this point, magnets 305 are held by tip 307. FIG. 4E shows magnets 305 being aligned adjacent to MEMS device 410 after removal of probe 300 from substrate 410. Finally, FIG. 4E shows the final configuration of MEMS device 410 on substrate 400, with adjacent magnets 305.

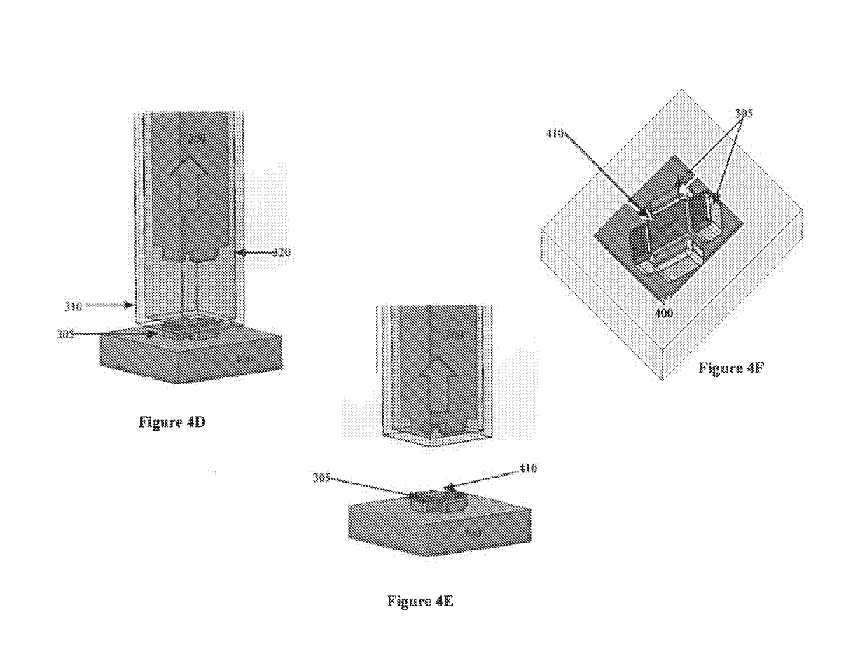

FIG. 5 is a graph illustrating one embodiment of implementation of a magnetic probe 300 having a magnetic force of a small (e.g., 1.5 mm×1.5 mm×3 mm) neodymium magnet attracting to a ferromagnetic material measured as a function of distance. The graph data indicates that small neodymium magnets can exert a significant amount of force when they are approaching a magnetic surface. Thus, a magnetic pick and place probe would be able to pull magnets and have sufficient force to self-align them. The graph also indicates that a retraction of approximately 2 mm is sufficient to reduce the magnetic force to almost zero.

Referring back to FIG. 1, system 100 includes a heat source to heat a probe, for example, while gripper 140 grasps a probe 125 on substrate 115A. As discussed above, heating of a probe may be desired to repair a configuration of a probe that is connected to a probe card substrate or to affix a probe to a probe card substrate. FIG. 1 shows heat source 170 that is representatively a resistive heat source.

System 100 of FIG. 1 also includes vision module 150. Vision module 150 includes imaging submodule 150 that has a field of view including probe card substrate 115A, one or more probes on substrate 115A and a portion of gripper 140 including the entire portion. Vision module 150 also includes a reproduction submodule connected to the imaging submodule to reproduce the field of view of the submodule on a screen, such as screen associated with processor 145. Vision module 150 permits optical metrology testing of probes and allows an operator to view the repair or assembling of the probe card substrate, such as probe card substrate 115A, and may also be used to identify a location on a probe card substrate for assembly or repair using positioning instructions.

In the embodiment illustrated in FIG. 1, system 100 also includes testing module 180. Testing module 180 is connected to processor 145 and, in one embodiment, is in a second area of platform 110 away from substrate 120. FIG. 1 shows probe card substrate 115B that is, for example, an assembled or repaired probe card substrate on platform 110 that may be undergoing testing by testing module 180. Testing module 180 is configured to test a probe that is connected to a probe card substrate or a series of probes connected to the probe card substrate. In one embodiment, testing module 180 includes conductor plate 185 for planarity measurements. Representatively, testing module 180 also includes submodule 190 that may be used, representatively, to test the continuity of individual probes and for spring constant measuring.

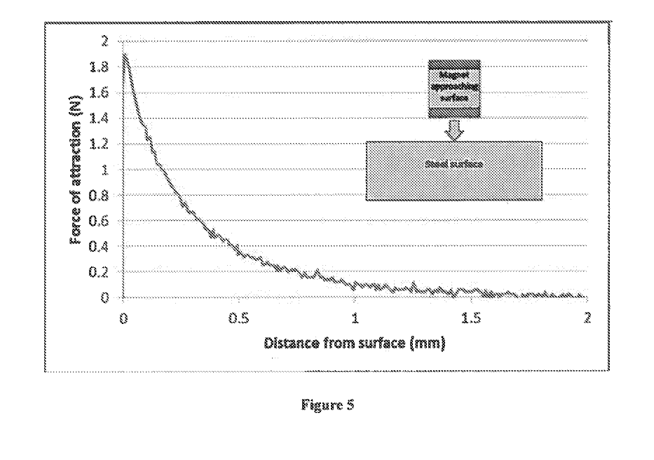

FIG. 6 shows another embodiment of a system. System 800 includes platform 810 onto which substrate 820 is mounted. Substrate 820, in one embodiment, is stationary and in another embodiment, is translatable in an x- and a z-direction similar to substrate 120 in FIG. 1 by instructions provided by processor 845.

Referring again to FIG. 5, also connected to processor 845 is robot 830. As described above, robot 830 may take various forms or configurations, consistent with its intended purpose. Connected to robot 830 is an end effector such as gripper 840. Robot 830 is configured to move in a work envelope. That work envelope includes movement in a y-direction (e.g., up or down as viewed). In this embodiment, robot is connected to first track 812 that extends in a z-direction at least the length of substrate 820. The z-position of track 812 is fixed to define a z-direction work envelope of robot 130. Track 812 is translatably connected to track 814 by, for example rails. Track 814 extends in an x-direction with the x-position of track 814 fixed to define an x-direction work envelope of robot 830. FIG. 6 shows a top view of substrate 820 and illustrates track 812 and track 814. Control of the translation of track 812 and robot 830 is provided by machine-readable instructions in processor 845 to which track 812 and robot 830 are connected through a motor. FIG. 6 also shows track 812 extends to area 888 that is, for example, an area where stored probes may be located.

Other features of system 800 are similar to that of system 100 in FIG. 1. Those features include vision module 860 connected to robot 830 and testing module 880.

References to “one embodiment”, “an embodiment”, “example embodiment”, “various embodiments”, etc., indicate that the embodiment(s) so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

As used in the claims, unless otherwise specified the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

The following clauses and/or examples pertain to further embodiments or examples. Specifics in the examples may be used anywhere in one or more embodiments. The various features of the different embodiments or examples may be variously combined with some features included and others excluded to suit a variety of different applications. Examples may include subject matter such as a method, means for performing acts of the method, at least one machine-readable medium including instructions that, when performed by a machine cause the machine to performs acts of the method, or of an apparatus or system for facilitating hybrid communication according to embodiments and examples described herein.

Some embodiments pertain to Example 1 that includes a magnetic pick and place probe comprising an outer sheath, an inner sheath to vertically slide within the outer sheath, one or more sheath magnets attached to a bottom end of the inner sheath and a tip positioned at a bottom end of the outer sheath to simultaneously pick up an array of magnets for placement on a substrate.

Example 2 includes the subject matter of Example 1, wherein the sheath magnets are positioned against the tip when the inner sheath is positioned at a bottom end of the outer sheath.

Example 3 includes the subject matter of Example 1 and 2, wherein the sheath magnets align each the array of magnets with the tip via a magnetic force while the sheath magnets are positioned against the tip.

Example 4 includes the subject matter of Example 1-3, wherein the sheath magnets control alignment of the each the array of magnets in an x-y plane.

Example 5 includes the subject matter of Example 1-4, wherein the tip controls alignment of the each the array of magnets in a z plane.

Example 6 includes the subject matter of Example 1-5, wherein the sheath magnets are disengaged from the tip upon sliding the inner sheath from the bottom end of the outer sheath.

Example 7 includes the subject matter of Example 1-6, wherein the magnetic force is removed on the array of magnets upon the sheath magnets being disengaged from the tip.

Example 8 includes the subject matter of Example 1-7, wherein the array of magnets is held the tip upon the sheath magnets being disengaged from the tip.

Some embodiments pertain to Example 9 that includes an apparatus comprising a substrate and a magnetic pick and place probe, including an outer sheath, an inner sheath to vertically slide within the outer sheath, one or more sheath magnets attached to a bottom end of the inner sheath and a tip positioned at a bottom end of the outer sheath to simultaneously pick up an array of magnets for placement on the substrate.

Example 10 includes the subject matter of Example 9, wherein the sheath magnets are positioned against the tip when the inner sheath is positioned at a bottom end of the outer sheath.

Example 11 includes the subject matter of Example 9 and 10, wherein the sheath magnets align each the array of magnets with the tip via a magnetic force while the sheath magnets are positioned against the tip.

Example 12 includes the subject matter of Example 9-11, wherein the sheath magnets control alignment of the each the array of magnets in an x-y plane.

Example 13 includes the subject matter of Example 9-12, wherein the tip controls alignment of the each the array of magnets in a z plane.

Example 14 includes the subject matter of Example 9-13, further comprising a Micro-electro-mechanical systems (MEMS) device mounted on the substrate.

Example 15 includes the subject matter of Example 9-14, wherein the probe places the array of magnets on the substrate in alignment with the MEMS device.

Example 16 includes the subject matter of Example 9-15, wherein the inner sheath is pulled away from the bottom end of the outer sheath upon placement of the array of magnets on the substrate.

Example 17 includes the subject matter of Example 9-16, wherein the sheath magnets are disengaged from the tip upon the inner sheath being pulled from the bottom end of the outer sheath.

Example 18 includes the subject matter of Example 9-17, wherein the magnetic force is removed on the array of magnets upon the sheath magnets being disengaged from the tip.

Example 19 includes the subject matter of Example 9-18, wherein the array of magnets is held the tip upon the sheath magnets being disengaged from the tip.

Some embodiments pertain to Example 20 that includes an apparatus comprising a substrate and a magnetic pick and place probe, including an outer sheath an inner sheath to vertically slide within the outer sheath, one or more sheath magnets attached to a bottom end of the inner sheath and a tip positioned at a bottom end of the outer sheath to simultaneously pick up an array of magnets for placement on the substrate, a robot and a gripper coupled to the robot to grasp the probe.

Example 21 includes the subject matter of Example 20, wherein the sheath magnets are positioned against the tip when the inner sheath is positioned at a bottom end of the outer sheath.

Example 22 includes the subject matter of Example 20 and 21, wherein the sheath magnets align each the array of magnets with the tip via a magnetic force while the sheath magnets are positioned against the tip.

Example 23 includes the subject matter of Example 20-22, wherein the sheath magnets control alignment of the each the array of magnets in an x-y plane and the tip controls alignment of the each the array of magnets in a z plane.

Example 24 includes the subject matter of Example 20-23, further comprising a Micro-electro-mechanical systems (MEMS) device mounted on the substrate, wherein the probe places the array of magnets on the substrate in alignment with the MEMS device.

Example 25 includes the subject matter of Example 20-24, wherein the inner sheath is pulled away from the bottom end of the outer sheath upon placement of the array of magnets on the substrate and the sheath magnets are disengaged from the tip upon the inner sheath being pulled from the bottom end of the outer sheath.

Although embodiments of the invention have been described in language specific to structural features and/or methodological acts, it is to be understood that claimed subject matter may not be limited to the specific features or acts described. Rather, the specific features and acts are disclosed as sample forms of implementing the claimed subject matter.

What is claimed is:

1. A magnetic pick and place probe, comprising:
an outer sheath;
an inner sheath to vertically slide within the outer sheath;
one or more sheath magnets attached to a bottom end of the inner sheath; and
a tip positioned at a bottom end of the outer sheath to simultaneously pick up an array of magnets for placement on a substrate.

2. The probe of claim 1 wherein the sheath magnets are positioned against the tip when the inner sheath is positioned at a bottom end of the outer sheath.

3. The probe of claim 2 wherein the sheath magnets align each the array of magnets with the tip via a magnetic force while the sheath magnets are positioned against the tip.

4. The probe of claim 3 wherein the sheath magnets control alignment of the each the array of magnets in an x-y plane.

5. The probe of claim 4 wherein the tip controls alignment of the each the array of magnets in a z plane.

6. The probe of claim 2 wherein the sheath magnets are disengaged from the tip upon sliding the inner sheath from the bottom end of the outer sheath.

7. The probe of claim 6 wherein the magnetic force is removed on the array of magnets upon the sheath magnets being disengaged from the tip.

8. The probe of claim 7 wherein the array of magnets is held the tip upon the sheath magnets being disengaged from the tip.

9. An apparatus comprising:
a substrate; and
a magnetic pick and place probe, including:
an outer sheath;
an inner sheath to vertically slide within the outer sheath;
one or more sheath magnets attached to a bottom end of the inner sheath; and
a tip positioned at a bottom end of the outer sheath to simultaneously pick up an array of magnets for placement on the substrate.

10. The apparatus of claim 9 wherein the sheath magnets are positioned against the tip when the inner sheath is positioned at a bottom end of the outer sheath.

11. The apparatus of claim 10 wherein the sheath magnets align each the array of magnets with the tip via a magnetic force while the sheath magnets are positioned against the tip.

12. The apparatus of claim 11 wherein the sheath magnets control alignment of the each the array of magnets in an x-y plane.

13. The apparatus of claim 12 wherein the tip controls alignment of the each the array of magnets in a z plane.

14. The apparatus of claim 10 further comprising a Micro-electro-mechanical systems (MEMS) device mounted on the substrate.

15. The apparatus of claim 14 wherein the probe places the array of magnets on the substrate in alignment with the MEMS device.

16. The apparatus of claim 15 wherein the inner sheath is pulled away from the bottom end of the outer sheath upon placement of the array of magnets on the substrate.

17. The apparatus of claim 16 wherein the sheath magnets are disengaged from the tip upon the inner sheath being pulled from the bottom end of the outer sheath.

18. The apparatus of claim 17 wherein the magnetic force is removed on the array of magnets upon the sheath magnets being disengaged from the tip.

19. The apparatus of claim 18 wherein the array of magnets is held the tip upon the sheath magnets being disengaged from the tip.

20. An apparatus comprising:
a substrate; and
a magnetic pick and place probe, including:
an outer sheath;
an inner sheath to vertically slide within the outer sheath;
one or more sheath magnets attached to a bottom end of the inner sheath; and
a tip positioned at a bottom end of the outer sheath to simultaneously pick up an array of magnets for placement on the substrate;
a robot; and
a gripper coupled to the robot to grasp the probe.

21. The apparatus of claim 20 wherein the sheath magnets are positioned against the tip when the inner sheath is positioned at a bottom end of the outer sheath.

22. The apparatus of claim 21 wherein the sheath magnets align each the array of magnets with the tip via a magnetic force while the sheath magnets are positioned against the tip.

23. The apparatus of claim 22 wherein the sheath magnets control alignment of the each the array of magnets in an x-y plane and the tip controls alignment of the each the array of magnets in a z plane.

24. The apparatus of claim 21 further comprising a Micro-electro-mechanical systems (MEMS) device mounted on the substrate, wherein the probe places the array of magnets on the substrate in alignment with the MEMS device.

25. The apparatus of claim 24 wherein the inner sheath is pulled away from the bottom end of the outer sheath upon placement of the array of magnets on the substrate and the sheath magnets are disengaged from the tip upon the inner sheath being pulled from the bottom end of the outer sheath.
